(19) United States
(12) Patent Application Publication
(10) Pub. No.: US 2026/0331862 A1
(43) Pub. Date: Oct. 22, 2026

(54) OPTICAL MODULE

(71) Applicant: NEC Corporation, Tokyo (JP)

(72) Inventors: Hiroki YASUDA, Tokyo (JP); Isao TOMITA, Tokyo (JP); Naoki KOBAYASHI, Tokyo (JP); Morio TAKAHASHI, Tokyo (JP); Ryo KURAHASHI, Tokyo (JP)

(73) Assignee: NEC Corporation, Tokyo (JP)

(21) Appl. No.: 19/640,543

(22) Filed: Apr. 7, 2026

(30) Foreign Application Priority Data
Apr. 16, 2025 (JP) 2025-067552

(51) Int. Cl. H01S 5/024; H01S 5/02

(52) U.S. Cl. CPC H01S 5/02469; H01S 5/021

(57) ABSTRACT

An optical module according to the present disclosure includes a temperature control element, a heat conductive member disposed so as to overlap the temperature control element, and a silicon photonics substrate disposed so as to overlap the heat conductive member and provided with an optical resonator using a silicon optical waveguide. The heat conductive member is installed so as to provide a space immediately below a part of the silicon photonics substrate.

### INCORPORATION BY REFERENCE

This application is based upon and claims the benefit of priority from Japanese patent application No. 2025-067552, filed on Apr. 16, 2025, the disclosure of which is incorporated herein in its entirety by reference.

### TECHNICAL FIELD

The present disclosure relates to an optical module.

### BACKGROUND ART

In recent years, there is an increasing need for a wavelength tunable laser using silicon photonics (SiPh). The wavelength tunable laser using SiPh includes a SiPh chip in which an optical resonator such as a ring resonator is installed and which functions as a wavelength tunable optical resonator.

In an optical module on which a SiPh chip functioning as a wavelength tunable optical resonator is mounted, the SiPh chip is installed on a temperature control element including a Peltier element in order to control the temperature of the SiPh chip. A heat conductive member is disposed between the temperature control element and the SiPh chip in order to make the heat distribution in the planar direction of the SiPh chip uniform and to adjust the height of the SiPh chip. That is, the heat conductive member is installed on the temperature control element, and the SiPh chip is installed on the heat conductive member.

Here, characteristics of an element such as an optical resonator on the SiPh chip change due to stress. Therefore, recently, a technology for reducing stress transmitted to a region where an optical resonator or the like on a SiPh chip is installed has been proposed.

For example, JP 2008-193003 A discloses a technology for preventing stress generated due to warpage of a temperature control element from being transmitted to an optical resonator on a SiPh chip. Specifically, in the technology disclosed in JP 2008-193003 A, a notch is provided in the heat conductive member in a portion immediately below the optical resonator on the SiPh chip so that the heat conductive member and the temperature control element are not in contact with each other.

### SUMMARY

In the technology disclosed in JP 2008-193003 A, the heat conductive member and the temperature control element are not in contact with each other in a portion immediately below a region where the optical resonator is installed on the SiPh chip. Therefore, it is possible to prevent the stress generated due to the warpage of the temperature control element from being transmitted to the region where the optical resonator on the SiPh chip is installed.

However, in the technology disclosed in JP 2008-193003 A, the SiPh chip is installed on the heat conductive member. Therefore, stress is generated due to a difference in linear expansion coefficient between the SiPh chip and the heat conductive member, or residual stress is generated in a case where an adhesive for fixing the SiPh chip and the heat conductive member is hardened. However, JP 2008-193003 A does not disclose at all that the stress is prevented from being transmitted to the region where the optical resonator on the SiPh chip is installed.

Therefore, in the technology disclosed in JP 2008-193003 A, there remains a problem that stress is transmitted to a region where the optical resonator on the SiPh chip is installed.

Therefore, in view of the above-described problems, an example object of the present disclosure is to provide an optical module capable of reducing stress transmitted to a specific region on a SiPh chip.

An optical module according to an example aspect includes
a temperature control element,
a heat conductive member disposed so as to overlap the temperature control element, and
a silicon photonics substrate disposed so as to overlap the heat conductive member and provided with an optical resonator using a silicon optical waveguide,
in which the heat conductive member is installed so as to provide a space immediately below a part of the silicon photonics substrate.

According to the above-described example aspect, it is possible to provide an optical module capable of reducing stress transmitted to a specific region on the SiPh chip.

### BRIEF DESCRIPTION OF DRAWINGS

The above and other aspects, features and advantages of the present disclosure will become more apparent from the following description of certain exemplary embodiments, taken in conjunction with the accompanying drawings, in which:

FIG. 1 is a side view illustrating a configuration example of an optical module according to the present disclosure;

FIG. 2 is a side view illustrating a modified configuration example of the optical module illustrated in FIG. 1;

FIG. 3 is a side view illustrating a modified configuration example of the optical module illustrated in FIG. 1; and

FIG. 4 is a side view illustrating a configuration example of an optical module according to the present disclosure.

### EXAMPLE EMBODIMENTS

Hereinafter, example embodiments of the present disclosure will be described below with reference to the drawings. The following description and drawings are omitted and simplified as appropriate for clarity of description. In the following drawings, the same elements are denoted by the same reference signs, and redundant description will be omitted as necessary.

### First Example Embodiment

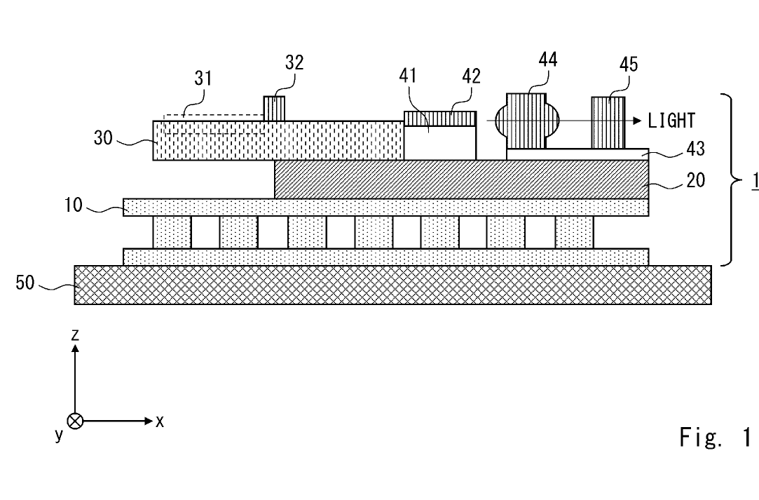

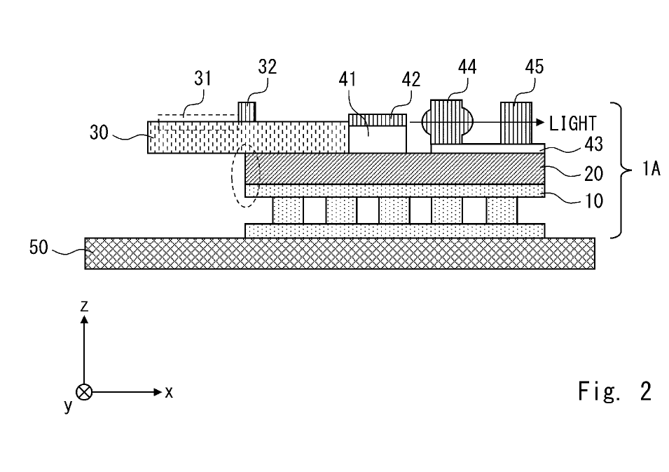

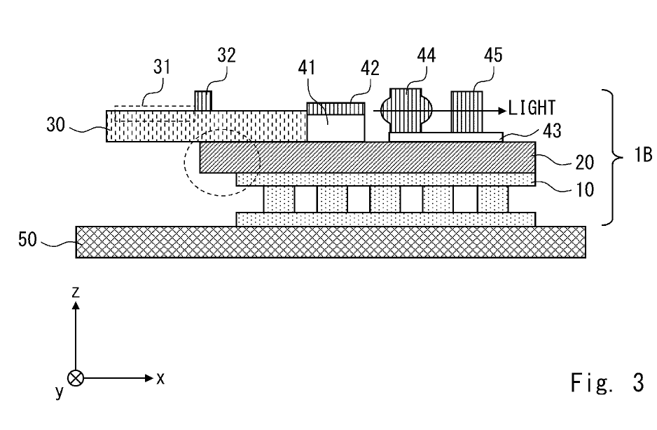

FIG. 1 is a side view illustrating a configuration example of an optical module 1 according to the present disclosure. FIG. 1 illustrates the optical module 1 in a state of being accommodated in a package 50. The package 50 has, for example, a rectangular parallelepiped shape in order to accommodate the optical module 1, but in FIG. 1, only a bottom surface portion of the package 50 is illustrated (the same applies to FIGS. 2 and 3).

As illustrated in FIG. 1, the optical module 1 includes a temperature control element 10, a heat conductive member 20, a SiPh chip 30, a thermistor 32, a pedestal 41, an optical amplifier 42, a pedestal 43, a lens 44, and an isolator 45.

The temperature control element 10 is an element for performing temperature control of the SiPh chip 30. For example, the temperature control element 10 includes a Peltier element.

The heat conductive member 20 is a member for making the heat distribution of the SiPh chip 30 in the planar direction (xy plane direction) uniform and for adjusting the height (z direction) of the SiPh chip 30, and is disposed so as to overlap the temperature control element 10. For example, the heat conductive member 20 is made of copper or ceramic.

The SiPh chip 30 is a chip that functions as a wavelength tunable optical resonator, and is disposed so as to overlap the heat conductive member 20. A ring resonator (not illustrated) which is an optical resonator configured using a Si waveguide is installed in a region 31 of the SiPh chip 30. Another element such as a modulator may be additionally installed in the region 31 of the SiPh chip 30. In FIG. 1, the thermistor 32 functioning as a temperature sensor is installed in a region other than the region 31 of the SiPh chip 30.

In a region where the SiPh chip 30 on the heat conductive member 20 (the positive side in the z direction. Hereinafter, the same applies) is not disposed, the pedestals 41 and 43 are installed. The optical amplifier 42 is installed on the pedestal 41, and the lens 44 and the isolator 45 are installed on the pedestal 43.

The ring resonator installed in the SiPh chip 30 is an element that changes the wavelength of light to a specific wavelength and outputs the light. The optical amplifier 42 is an element that amplifies and outputs the light output from the SiPh chip 30. The lens 44 is an element that collimates the light output from the optical amplifier 42 and couples the light to an optical fiber (not illustrated) together with a condensing second lens (not illustrated). The isolator 45 is an element that transmits the light output from the lens 44 only in the direction of the optical fiber.

Here, in the optical module 1, the heat conductive member 20 is installed such that the end portion on the negative side in the x direction of the heat conductive member 20 is located on the positive side in the x direction with respect to the end portions on the negative side in the x direction of the temperature control element 10 and the SiPh chip 30.

Therefore, a space is formed immediately below a part on the negative side in the x direction of the SiPh chip 30 (the negative side in the z direction. Hereinafter, the same applies), specifically, immediately below the region 31 where the ring resonator and the like on the SiPh chip 30 are installed.

As described above, since the optical module 1 has a structure in which a space is formed immediately below the region 31 where the ring resonator and the like of the SiPh chip 30 are installed, various advantageous effects can be obtained as compared with the technology disclosed in JP 2008-193003 A. Hereinafter, effects of the optical module 1 will be described in comparison with the technology disclosed in JP 2008-193003 A.

In the technology disclosed in JP 2008-193003 A, the SiPh chip is installed on the heat conductive member. Therefore, stress is generated due to a difference in linear expansion coefficient between the SiPh chip and the heat conductive member, or residual stress is generated in a case where an adhesive for fixing the SiPh chip and the heat conductive member is hardened. These stresses are transmitted to a region where the optical resonator on the SiPh chip is installed. As a result, the temporal change of the stress applied to the SiPh chip accompanying the relaxation of the residual stress occurs, so that the characteristics of the optical resonator are changed and the long-term reliability is impaired.

On the other hand, since the optical module 1 has a structure in which a space is formed immediately below the region 31 where the ring resonator or the like of the SiPh chip 30 is installed, the SiPh chip 30 does not come into contact with the heat conductive member 20 at a portion immediately below the region 31. Therefore, in the optical module 1, in a portion immediately below the region 31, the stress caused by the SiPh chip being installed on the heat conductive member as in the technology disclosed in JP 2008-193003 A is not generated. As a result, stress transmitted to the region 31 on the SiPh chip 30 can be reduced, and a change in characteristics of the optical resonator due to a change with time of the stress can be eliminated.

In the technology disclosed in JP 2008-193003 A, it is necessary to form a notch in the heat conductive member. Therefore, the heat conductive member has a special shape in which a notch is formed, and the price of the heat conductive member increases.

On the other hand, in the optical module 1, it is not necessary to form a notch in the heat conductive member 20, so that the heat conductive member 20 can have a simple shape. Accordingly, the heat conductive member 20 can be achieved at low cost.

In the technology disclosed in JP 2008-193003 A, the temperature control element and the heat conductive member are fixed with an adhesive in a portion other than a portion immediately below the optical resonator. At this time, if the amount of the adhesive is not strictly controlled, since the interval between the notches formed in the heat conductive member is as narrow as about 100 μm, the adhesive enters the space portion, and the effect of reducing the stress caused by the warpage of the temperature control element is weakened. Therefore, strict control of the amount of adhesive is required.

On the other hand, in the optical module 1, it is not necessary to form notches with a narrow interval in the heat conductive member 20, so that the adhesive does not enter the space portion. Therefore, strict control of the amount of the adhesive becomes unnecessary.

### Modified Example of First Example Embodiment

FIGS. 2 and 3 are side views illustrating a modified configuration example of the optical module 1 illustrated in FIG. 1.

In the optical module 1 illustrated in FIG. 1, the end portion on the negative side in the x direction of the temperature control element 10 is located on the negative side in the x direction with respect to the end portion on the negative side in the x direction of the heat conductive member 20. As a result, a space immediately below a part of the SiPh chip 30 is formed between a part of the SiPh chip 30 and the temperature control element 10. However, the present disclosure is not limited thereto.

For example, as in an optical module 1A illustrated in FIG. 2, the end portion on the negative side in the x direction of the temperature control element 10 and the end portion on the negative side in the x direction of the heat conductive member 20 may be matched at the position in the x direction. As a result, a space may be formed between a part of the SiPh chip 30 and the bottom surface of the package 50.

Alternatively, as in an optical module 1B illustrated in FIG. 3, the end portion on the negative side in the x direction of the temperature control element 10 may be located on the positive side in the x direction with respect to the end portion on the negative side in the x direction of the heat conductive member 20. As a result, a space may be formed between a part of the SiPh chip 30 and the bottom surface of the package 50.

### Second Example Embodiment

A second example embodiment is relevant to an example embodiment that is a superordinate concept of the first example embodiment described above.

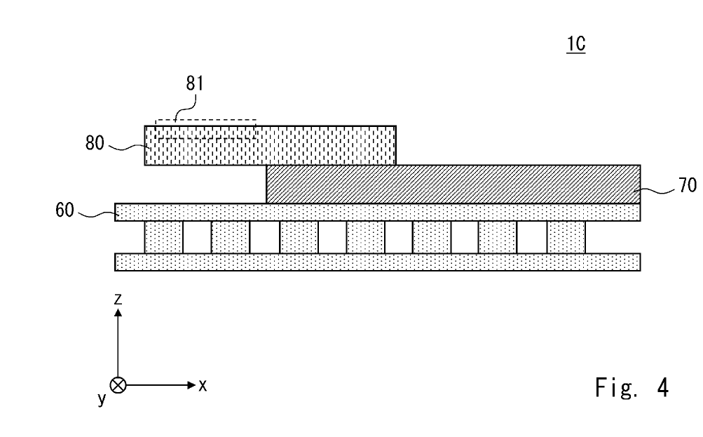

FIG. 4 is a side view illustrating a configuration example of an optical module 1C according to the present disclosure.

As illustrated in FIG. 4, the optical module 1C includes a temperature control element 60, a heat conductive member 70, and a silicon photonics substrate 80. The temperature control element 60 is relevant to the temperature control element 10, the heat conductive member 70 is relevant to the heat conductive member 20, and the silicon photonics substrate 80 is relevant to the SiPh chip 30.

The heat conductive member 70 is disposed so as to overlap the temperature control element 60.

The silicon photonics substrate 80 is disposed so as to overlap the heat conductive member 70, and an optical resonator using a silicon optical waveguide is installed.

The heat conductive member 70 is installed so as to provide a space immediately below a part of the silicon photonics substrate 80.

As described above, since the optical module 1C has a structure in which a space is provided immediately below a part of the silicon photonics substrate 80, the silicon photonics substrate 80 does not come into contact with the heat conductive member 70 at a portion immediately below a part of the silicon photonics substrate 80. Therefore, in the optical module 1C, in a portion immediately below a part of the silicon photonics substrate 80, as in the technology disclosed in JP 2008-193003 A, a stress caused by the SiPh chip being installed on the heat conductive member is not generated. As a result, the stress transmitted to the region relevant to a part of the silicon photonics substrate 80 can be reduced, and the temporal characteristic change of the optical resonator due to the temporal change of the stress can be reduced.

The heat conductive member 70 may be installed so as to provide a space between a part of the silicon photonics substrate 80 and the temperature control element 60.

The optical module 1C may be accommodated in a package. The heat conductive member 70 may be installed so as to provide a space between a part of the silicon photonics substrate 80 and the bottom surface of the package.

The space may be provided immediately below a region 81 where the optical resonator is installed in the silicon photonics substrate 80.

While the present disclosure has been particularly shown and described with reference to example embodiments thereof, the present disclosure is not limited to these example embodiments. It will be understood by those of ordinary skill in the art that various changes in form and details may be made therein without departing from the spirit and scope of the present disclosure as defined by the claims. And each example embodiment can be appropriately combined with other example embodiments.

Each of the drawings is merely illustrative for describing one or more example embodiments. Each drawing is not associated with only one specific example embodiment, but may be associated with one or more other example embodiments. As those skilled in the art will appreciate, various features described with reference to any one of the drawings may be combined with features illustrated in one or more other drawings, for example, to create an example embodiment that is not explicitly illustrated or described. All of the features illustrated in any one of the drawings for describing the exemplary example embodiments are not necessarily mandatory, and some features may be omitted.

Some or all of the above example embodiments may be described as the following Supplementary Notes, but are not limited to the following.

### Supplementary Note 1

An optical module including:
a temperature control element;
a heat conductive member disposed so as to overlap the temperature control element; and
a silicon photonics substrate disposed so as to overlap the heat conductive member and provided with an optical resonator using a silicon optical waveguide,
in which the heat conductive member is installed so as to provide a space immediately below a part of the silicon photonics substrate.

### Supplementary Note 2

The optical module according to Supplementary Note 1, in which the heat conductive member is installed so as to provide the space between the part of the silicon photonics substrate and the temperature control element.

### Supplementary Note 3

The optical module according to Supplementary Note 1, in which
the optical module is housed in a package, and
the heat conductive member is installed so as to provide the space between the part of the silicon photonics substrate and a bottom surface of the package.

### Supplementary Note 4

The optical module according to Supplementary Note 1, in which the space is provided immediately below a region where the optical resonator is installed in the silicon photonics substrate.

What is claimed is:

1. An optical module comprising:
a temperature control element;
a heat conductive member disposed so as to overlap the temperature control element; and
a silicon photonics substrate disposed so as to overlap the heat conductive member and provided with an optical resonator using a silicon optical waveguide,
wherein the heat conductive member is installed so as to provide a space immediately below a part of the silicon photonics substrate.

2. The optical module according to claim 1, wherein the heat conductive member is installed so as to provide the space between the part of the silicon photonics substrate and the temperature control element.

3. The optical module according to claim 1, wherein
the optical module is housed in a package, and
the heat conductive member is installed so as to provide the space between the part of the silicon photonics substrate and a bottom surface of the package.

4. The optical module according to claim 1, wherein the space is provided immediately below a region where the optical resonator is installed in the silicon photonics substrate.
